(19) United States
(12) Patent Application Publication
(10) Pub. No.: US 2025/0202362 A1
(43) Pub. Date: Jun. 19, 2025

(54) LOOP CONTROL METHODOLOGY AND CONTROL CIRCUIT FOR HIGH FREQUENCY SWITCHING CONVERTER

(71) Applicant: Monolithic Power Systems, Inc., Kirkland, WA (US)

(72) Inventors: Wen-Jie Tsou, New Taipei City (TW); Bor-Tsang Hwang, New Taipei City (TW); Yu-Huei Lee, New Taipei City (TW); Haoyang You, San Jose, CA (US)

(21) Appl. No.: 18/981,082

(22) Filed: Dec. 13, 2024

Related U.S. Application Data
(60) Provisional application No. 63/610,640, filed on Dec. 15, 2023.

(51) Int. Cl. H02M 3/158; H02M 3/157; H03K 4/06; H03K 7/08

(52) U.S. Cl. CPC H02M 3/158; H02M 3/157; H03K 4/06; H03K 7/08

(57) ABSTRACT

A control circuit for a switching converter includes a compensation circuit, a ramp generation circuit, a comparison circuit and a logic circuit. The compensation circuit is configured to generate a compensation signal in response to a feedback signal and a reference signal. The ramp generation circuit is configured to generate a ramp signal. The comparison circuit is configured to provide a comparison signal in response to the compensation signal and the ramp signal. The logic circuit is configured to provide the PWM control signal to the switching converter. The PWM control signal is at a first voltage level when a value of the ramp signal reaches a value of the compensation signal. The PWM control signal is at a second voltage level in response to the clock signal.

### CROSS-REFERENCE TO RELATED APPLICATION(S)

The present application claims the benefit of and priority to a U.S. Provisional Patent Application Ser. 63/610,640 filed Dec. 15, 2023, which is hereby incorporated fully by reference into the present application.

### TECHNICAL FIELD

The present disclosure relates generally to power circuits, and more particularly but not exclusively to switching converters.

### BACKGROUND OF THE INVENTION

Power converters such as switch mode voltage regulators are widely used to provide power to electronic devices. COT (Constant On-Time) control has been widely used with DC/DC voltage converters for its fast transient response. However, the switching frequency of the COT controlled voltage converter is variable and not constant, which makes COT control hardly applied in cases where a constant switching frequency is essentially required, such as an automobile system. Contrarily, current mode control has a constant switching frequency, but it is slow in transient response, and the minimum on-time or off-time of a power switch during each switching cycle is required to implement current sensing function.

Consequently, a control circuit and scheme thereof with fast transient response and constant switching frequency is needed.

### SUMMARY OF THE INVENTION

According to an embodiment of the present disclosure, a control circuit for a switching converter is provided. The switching converter having at least one power switch is configured to covert an input voltage into an output voltage in response to a pulse-width modulation (PWM) control signal. The control circuit includes a compensation circuit, a ramp generation circuit, a comparison circuit and a logic circuit. The compensation circuit is configured to generate a compensation signal in response to the output voltage and a reference signal. The ramp generation circuit is configured to generate a ramp signal in response to the PWM control signal. The comparison circuit is configured to provide a comparison signal in response to the compensation signal and the ramp signal. The logic circuit is configured to provide the PWM control signal in response to the comparison signal and a clock signal.

According to another embodiment of the present disclosure, a control circuit for a switching converter is provided. The switching converter having at least one power switch is configured to covert an input voltage into an output voltage in response to a PWM control signal. The control circuit includes a compensation circuit, a ramp generation circuit, a comparison circuit and a logic circuit. The compensation circuit is configured to generate a compensation signal in response to a feedback signal representing the output voltage and a reference signal. The ramp generation circuit configured to generate a ramp signal. The comparison circuit is configured to provide a comparison signal in response to the compensation signal and the ramp signal. The logic circuit is configured to provide the PWM control signal in response to the comparison signal and a clock signal. The PWM control signal is at a first voltage level when a value of the ramp signal reaches a value of the compensation signal. The PWM control signal is at a second voltage level in response to the clock signal.

### BRIEF DESCRIPTION OF THE DRAWINGS

The present disclosure can be further understood with reference to the following detailed description and appended drawings, where like elements are provided with like reference numerals. These drawings are only for illustration purpose, thus may only show part of the devices and are not necessarily drawn to scale.

FIG. 1 is a block circuit diagram of a power converter in accordance with an embodiment of the present disclosure.

FIG. 2 is a schematic circuit diagram of a switching converter with a current mode control in accordance with an embodiment of the present disclosure.

FIG. 3 is a block circuit diagram of a control circuit for a switching converter in accordance with an embodiment of the present disclosure.

FIG. 4 is a block diagram of a ramp generation circuit in accordance with an embodiment of the present disclosure.

FIG. 5 is a schematic circuit diagram of a control circuit for a switching converter in accordance with an embodiment of the present disclosure.

FIG. 6 is a schematic circuit diagram of a ramp generation circuit in accordance with an embodiment of the present disclosure.

FIG. 7 is a schematic diagram of simulated waveforms of signals of the control circuit as shown in FIG. 5 in accordance with an embodiment of the present disclosure.

FIG. 8 is a schematic diagram of simulated waveforms of signals of the ramp generation circuit as shown in FIG. 6 in accordance with an embodiment of the present disclosure.

FIG. 9 is a flowchart of a method for controlling a switching converter in accordance with an embodiment of the present disclosure.

### DETAILED DESCRIPTION

Various embodiments of the present disclosure will now be described. In the following description, some specific details, such as example circuits and example values for these circuit components, are included to provide a thorough understanding of embodiments. One skilled in the relevant art will recognize, however, that the present disclosure can be practiced without one or more specific details, or with other methods, components, materials, etc. In other instances, well- known structures, materials, processes or operations are not shown or described in detail to avoid obscuring aspects of the present disclosure.

Throughout the specification and claims, the phrases “in one embodiment”, “in some embodiments”, “in one implementation”, and “in some implementations” as used includes both combinations and sub-combinations of various features described herein as well as variations and modifications thereof. These phrases used herein do not necessarily refer to the same embodiment, although it may. Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element, or indirectly connected to or coupled to the other element via another element. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

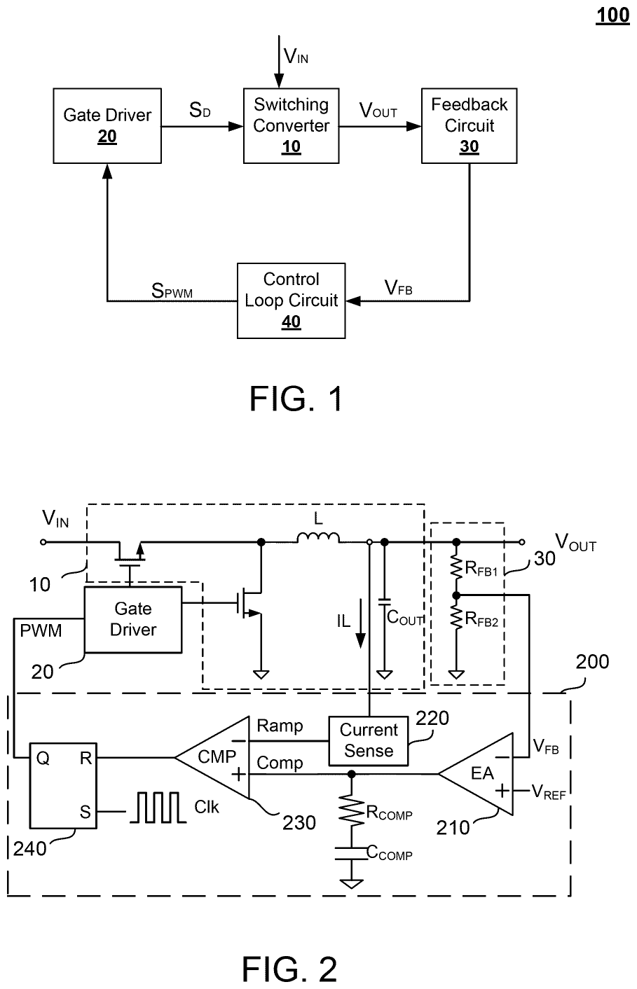

FIG. 1 is a block circuit diagram of a power converter 100 in accordance with an embodiment of the present disclosure. As shown in FIG. 1, the power converter 100 includes a switching converter 10, a gate driver 20, a feedback circuit 30 and a control loop circuit 40. The switching converter 10 has at least one power switch configured to covert an input voltage V_{IN} into an output voltage V_{OUT}. In one embodiment, the switching converter 10 is a buck converter. In another embodiment, the switching converter 10 is a boost converter. In yet another embodiment, the switching converter 10 is a buck-boost converter. However, the present disclosure is not limited thereto. In various embodiments, the switching converter 10 may be any types of power converter.

The feedback circuit 30 is configured to receive the output voltage V_{OUT} and provides a feedback signal V_{FB} proportional to the output voltage V_{OUT}. The control loop circuit 40 is configured to receive the feedback signal V_{FB} and provide a PWM control signal S_{PWM} to the gate driver 20. Accordingly, the gate driver 20 is configured to provide the driving signal (e.g., S_{D}) to at least one switch of the switching converter 10 in response to the PWM control signal S_{PWM}.

FIG. 2 is a schematic circuit diagram of a switching converter 10 with a current mode control in accordance with an embodiment of the present disclosure. As shown in FIG. 2, the control loop circuit 200 includes a compensation circuit 210, a current sense ramp circuit 220, a comparison circuit 230, and a logic circuit 240. The compensation circuit 210 (e.g., an error amplifier EA) is configured to receive the feedback signal V_{FB} and a reference signal V_{REF}, and generate a compensation signal Comp in response to the feedback signal V_{FB} and the reference signal V_{REF}. The current sense ramp circuit 220 is configured to sense the inductor current IL and generate the ramp signal Ramp in response to the inductor current IL. In some embodiments, the slope compensation circuit is used to generate the ramp signal Ramp. The comparison circuit 230 (e.g., a comparator CMP) is configured to receive the compensation signal Comp and the ramp signal Ramp and provide a comparison signal. The logic circuit 240 (e.g., a SR latch) is configured to receive the comparison signal and a clock signal Clk and provide the PWM control signal PWM.

However, for high frequency switching converter, using the current sense signal as the ramp signal is not ideal as it has a long settling time. Specifically, for automotive radar system, a fixed high-frequency buck converter is required. Since the baseband frequency of the radar system is wide, for example, from a few KHz to a few MHZ, the switching frequency of the power converter should be higher than 12 MHz. In one example, the switching frequency of the power converter is 18 MHz, each cycle is about 56 ns. For such a short time, it is hard to sense the inductor current IL with the settling time. Therefore, instead of sensing the inductor current IL, a PWM signal is filtered as the ramp signal for the high frequency switching converter.

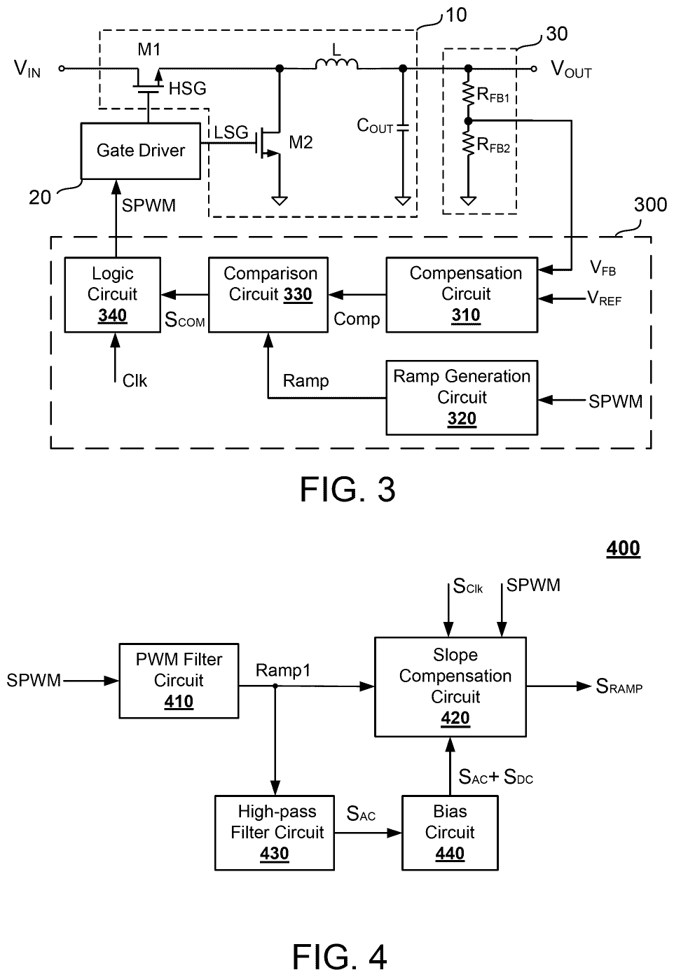

FIG. 3 is a block circuit diagram of a control circuit 300 for a switching converter in accordance with an embodiment of the present disclosure. The switching converter 10 has at least one power switch configured to covert an input voltage V_{IN} into an output voltage V_{OUT} in response to a PWM control signal SPWM. In one embodiment, the switching converter 10 is a buck converter. In another embodiment, the switching converter 10 is a boost converter. In yet another embodiment, the switching converter 10 is a buck-boost converter. However, the present disclosure is not limited thereto. In various embodiments, the switching converter 10 may be any types of power converter.

As shown in FIG. 3, a feedback circuit 30 is configured to receive the output voltage V_{OUT} and provides a feedback signal V_{FB} proportional to the output voltage V_{OUT}. For instance, the feedback signal V_{FB} is generated via a voltage divider (e.g., resistors R_{FB1} and R_{FB2}). The control circuit 300 is configured to receive the feedback signal V_{FB} and provide a PWM control signal SPWM to a gate driver 20. Accordingly, the gate driver 20 is configured to provide the driving signal (e.g., HSG, and LSG) to at least one switch of the switching converter 10 in response to the PWM control signal SPWM.

Specifically, the control circuit 300 includes a compensation circuit 310, a ramp generation circuit 320, a comparison circuit 330, and a logic circuit 340. The compensation circuit 310 is configured to receive the output voltage V_{OUT} and a reference signal V_{REF}, and generate a compensation signal Comp in response to the output voltage V_{OUT} and the reference signal V_{REF}. In one embodiment, a feedback signal V_{FB} representing the output voltage V_{OUT} is generated by the feedback circuit 30. The ramp generation circuit 320 is configured to receive the PWM control signal SPWM, and generate a ramp signal Ramp in response to the PWM control signal SPWM. The comparison circuit 330 is configured to receive the compensation signal Comp and the ramp signal Ramp, and provide a comparison signal S_{COM} in response to the compensation signal Comp and the ramp signal Ramp. The logic circuit 340 is configured to receive the comparison signal S_{COM} and a clock signal Clk, and provide the control signal SPWM to the gate driver 20 in response to the comparison signal S_{COM} and the clock signal Clk.

In one embodiment, the PWM control signal SPWM is at a first voltage level (e.g., HSG at a high voltage level or high logic level) to turn on the high side power switch (e.g., M1) when a value of the ramp signal (e.g., Ramp) reaches a value of the compensation signal (e.g., Comp). In one embodiment, the PWM control signal SPWM is at a second voltage level (e.g., HSG at a low voltage level or low logic level) to turn off the high side power switch (e.g., M1) in response to the clock signal clk.

FIG. 4 is a block diagram of a ramp generation circuit 400 in accordance with an embodiment of the present disclosure. As shown in FIG. 4, the ramp generation circuit 400 includes a PWM filter circuit 410, and a slope compensation circuit 420. The PWM filter circuit 410 is configured to filter the PWM control signal SPWM and generate a first ramp signal Ramp1. In one embodiment, the PWM filter circuit 410 includes a low pass filter to convert a square wave signal into a triangular wave signal. As a result, the first ramp signal Ramp1 is in phase with the inductor current IL of the switching converter 10.

The slope compensation circuit 420 is configured to generate the ramp signal S_{RAMP} in response to the first ramp signal Ramp1, the PWM control signal SPWM, and the clock signal S_{Clk}. The ramp signal S_{RAMP} is a periodic signal having a constant frequency set by the clock signal S_{Clk}. In one embodiment, the slope compensation circuit 420 includes a frequency control circuit to generate the ramp signal S_{RAMP} in response to an edge of a clock signal (e.g., a rising edge or a falling edge). Accordingly, the switching frequency of the high and low side power switches may be effectively locked to the constant frequency set by the clock signal S_{Clk}.

In one embodiment, the ramp generation circuit 400 further includes a high-pass filter circuit 430. The high-pass filter circuit 430 is configured to filter the first ramp signal Ramp 1 and generate a second ramp signal. For instance, a purely AC signal S_{AC} is passed, while the DC signal of the first ramp signal Ramp1 is filtered. Since the DC signal of the first ramp signal Ramp 1 is related to the PWM control signal, determined by the input voltage V_{IN} and the output voltage V_{OUT}, the second ramp signal (e.g., S_{AC}) is not affected by the output load transient, and thus the transient response is improved. In one embodiment, the ramp generation circuit 400 further includes a bias circuit 440. The bias circuit 440 is configured to receive the first ramp signal Ramp1 and adjust the DC bias (e.g., S_{DC}) of the first ramp signal Ramp1 to provide the ramp signal S_{RAMP} (e.g., S_{RAMP}=S_{AC}+S_{DC}). In one embodiment, the DC bias (e.g., S_{DC}) of the ramp signal S_{RAMP} is proportional to the input voltage (e.g., S_{DC}=k*V_{IN}).

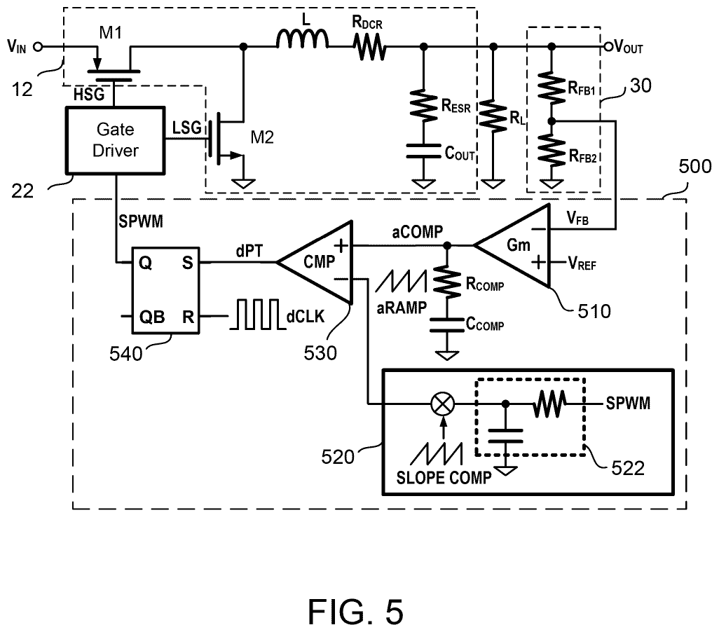

FIG. 5 is a schematic circuit diagram of a control circuit 500 for a switching converter 12 in accordance with an embodiment of the present disclosure. Similarly, the switching converter 12 is configured to receive an input voltage V_{IN}and provide an output voltage V_{OUT} to a load R_{L}. The gate driver 22 is configured to provide the driving signal (e.g., HSG, and LSG) to the power switches of the switching converter 12 in response to the control signal SPWM.

As shown in FIG. 5, the control circuit 500 includes a compensation circuit 510, a ramp generation circuit 520, a comparison circuit 530, and a logic circuit 540. The compensation circuit 510 is configured to receive the feedback signal V_{FB}and a reference signal V_{REF}, and generate a compensation signal aComp in response to the feedback signal V_{FB} and the reference signal V_{REF}. In one implementation, the compensation circuit 510 includes an error amplifier. The ramp generation circuit 520 is configured to receive the PWM control signal SPWM and provide a ramp signal aRAMP. In one implementation, the ramp generation circuit 520 further includes a PWM filter circuit 522 and a slope compensation circuit. In one implementation, the comparison circuit 530 includes a comparator CMP configured to receive the compensation signal aCOMP and the ramp signal aRAMP and provide a comparison signal dPT. In one implementation, the logic circuit 540 includes a SR latch configured to receive the comparison signal dPT at a set terminal and a clock signal dCLK at a reset terminal, and provide the PWM control signal SPWM to the gate driver 22.

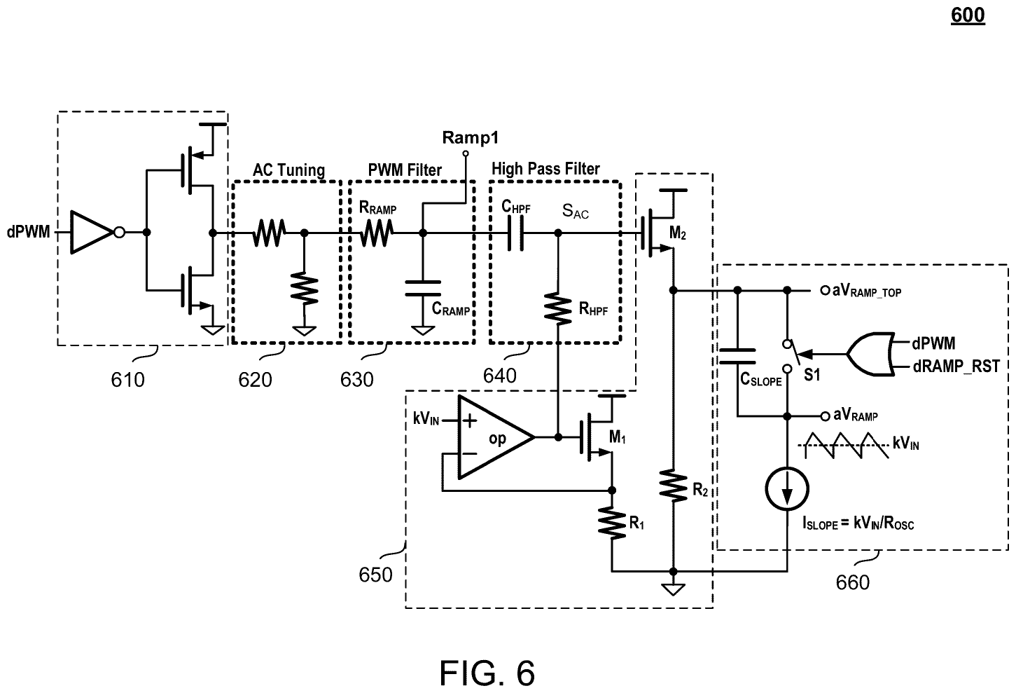

FIG. 6 is a schematic circuit diagram of a ramp generation circuit 600 in accordance with an embodiment of the present disclosure. In one embodiment, the ramp generation circuit 600 may be implemented in the control circuit 500 as shown in FIG. 5. In another embodiment, the ramp generation circuit 600 may be implemented in the control circuit 300 as shown in FIG. 3. As shown in FIG. 6, the ramp generation circuit 600 includes a PWM circuit 610, a PWM filter circuit 630, a high-pass filter circuit 640, a bias circuit 650, and a slope compensation circuit 660. For high frequency switching converter, using the current sense signal as the ramp signal is not ideal as it has a long settling time. Instead, a PWM control signal is filtered by the PWM filter circuit 630 as the ramp signal for the high frequency switching converter. For instance, the PWM filter circuit 630 includes a low pass filter to converte PWM control signal to a ramp signal. The resistor R_{RAMP} and the capacitor C_{RAMP} are connected in series to induce a zero in the control loop for phase margin boosting to improve stability. Specifically, a first terminal of the resistor R_{RAMP} is configured to receive the PWM control signal SPWM, and a second terminal of the resistor R_{RAMP} is coupled to a first terminal of the capacitor C_{RAMP} to provide the first ramp signal Ramp1.

In one embodiment, an AC tuning circuit 620 is configured to tune the AC amplitude of the PWM control signal. For instance, the AC tuning circuit 620 includes a voltage divider.

The first ramp signal Ramp1 is filtered by a high-pass filter circuit 640. For instance, the high-pass filter circuit 640 includes a capacitor C_{HPF} and a resistor R_{HPF} connected in series to pass the purely AC signal, while the DC signal of the first ramp signal Ramp1 that is related to the output voltage V_{OUT} is filtered. Specifically, a first terminal of the capacitor C_{HPF} is coupled to the first terminal of the capacitor C_{RAMP} to receive the first ramp signal Ramp1, and a second terminal of the capacitor C_{HPF} is coupled to a first terminal of the resistor R_{HPF} to provide the second ramp signal S_{AC}.

In one embodiment, the bias circuit 650 is configured to adjust the DC bias of the ramp signal aV_{RAMP}. In some cases, when the input voltage V_{IN} is at a lower value, while the output voltage V_{OUT} is at a higher value, the output voltage of the error amplifier (e.g., 510) will be at a higher value in response to the output voltage V_{OUT}. When the output voltage V_{OUT} is higher, the ramp signal Ramp1 is also higher, the compensation signal aCOMP would also be higher to reach the ramp signal aRAMP as shown in FIG. 5. In this case, the error amplifier (e.g., 510), which receive the lower input voltage V_{IN}, may not operate properly as the output voltage of the error amplifier (i.e., aCOMP) exceeds its operating range. In one embodiment, by tracking the input voltage V_{IN} and filtering the output voltage V_{OUT}, the output voltage of the error amplifier is also proportional to the input voltage. In other words, by setting the DC bias of the ramp signal aV_{RAMP} to be KV_{IN}, the PWM comparator (e.g., 530) could operate normally under low input voltage condition. Therefore, the output voltage of the error amplifier (e.g., 510) could be a fixed value at a steady state without affected by the output voltage V_{OUT} and the loading current of the switching converter 12, and thus the control circuit 500 could operate in a wider operating range (e.g., V_{OUT}). As the output voltage of the error amplifier (e.g., 510) is a constant, there is no need to charge or discharge the bulky compensator of the error amplifier (e.g., 510) during transient operation, and thus the transient recovery time is fast.

For instance, the bias circuit 650 includes an operational amplifier op. In one embodiment as shown in FIG. 6, the bias circuit 650 further includes transistors M₁ and M₂, and resistors R₁ and R₂. Specifically, the first input terminal of the operational amplifier op is configured to receive a bias voltage (e.g., KV_{IN}), and the output terminal of the operational amplifier op is coupled to the second terminal of the resistor R_{HPF} and the control terminal of the transistor M₁, and the second input terminal of the operational amplifier op is coupled to the second terminal of the transistor M₁ and the resistor R₁. The control terminal of the transistor M₂ is coupled to the first terminal of the resistor R_{HPF}, and the second terminal of the transistor M₂ (coupled to the resistor R₂) is configured to provide the ramp signal aV_{RAMP_TOP}. The transistor M₁ and M₂ should be the same device to achieve Vgs cancellation. By removing the Vgs from the DC bias of aV_{RAMP_TOP}, the process, voltage and temperature (PVT) variations of the transistor device will not affect the DC value (KV_{IN}) of the ramp signal aV_{RAMP}.

In one implementation, the slope compensation circuit 660 includes a compensation capacitor C_{SLOPE}, a current source I_{SLOPE}, and a control switch S1.

The current source I_{SLOPE} is configured to provide a charging current. The compensation capacitor C_{SLOPE} is coupled in series with the current source I_{SLOPE}. The first terminal of the compensation capacitor C_{SLOPE} is configured to receive the ramp signal SAC via the transistor M₂, and the second terminal of the compensation capacitor C_{SLOPE} is configured to provide the ramp signal aV_{RAMP}. The control switch S1 is coupled in parallel with the compensation capacitor C_{SLOPE}.

In the embodiment as shown in FIG. 6, the current source I_{SLOPE} is coupled between the compensation capacitor C_{SLOPE} and the ground to discharge the compensation capacitor C_{SLOPE}. Accordingly, the ramp signal aV_{RAMP} is reset by the control switch S1, and then pulled down to reach the compensation signal aCOMP. However, the present disclosure is not limited thereto. In another embodiment, the ramp signal aV_{RAMP} is reset by the control switch S1, and then pulled high to reach the compensation signal aCOMP. Accordingly, the current source I_{SLOPE} is coupled between the supply voltage and the compensation capacitor C_{SLOPE} to charge the compensation capacitor C_{SLOPE}.

The control switch S1 is controlled in response to the clock signal S_{Clk}. The ramp signal aV_{RAMP} is a periodic signal having a constant frequency set by the clock signal. For instance, the clock signal could be the clock signal Clk as shown in FIGS. 2-3, the signal S_{Clk} as shown in FIG. 4 or the signal dCLK as shown in FIG. 5. In one implementation, a signal dRAMP_RST is triggered at a rising edge or a falling edge of the clock signal (e.g., Clk, S_{Clk} or dCLK) to reset the ramp signal aV_{RAMP}. In one embodiment, the control switch is also controlled in response to the PWM control signal (e.g., dPWM). For example, the control switch S1 is reset by a signal (e.g., dPWM, or dRAMP_RST) for fixed frequency operation to avoid the switching frequency is lower than the target value. The compensation capacitor C_{SLOPE} and the current source I_{SLOPE} are configured to increase noise margin of the circuit. When switching at a high frequency, some noise occur on the ramp signal aV_{RAMP}. The noise on the ramp signal may trigger the PWM comparator falsely, which leads to unexpected behavior, such as false triggering oscillation. By adjusting the slope of the ramp signal to be steeper via the slope compensation circuit 660, the noise immunity is improved. In one implementation, the slope of the ramp signal aV_{RAMP} is determined by the current source I_{SLOPE}, which is determined by the input voltage V_{IN} and the resistor R_{OSC} is related to the switching frequency. For example, the resistance of the resistor R_{OSC} could be smaller for a higher switching frequency, while the resistance of the resistor R_{OSC} could be larger for a lower switching frequency. The value of the current source I_{SLOPE} is proportional to the input voltage V_{IN} to suppress phase degrade caused by the high-pass filter circuit. That is, the stability will not be affected by different input voltages.

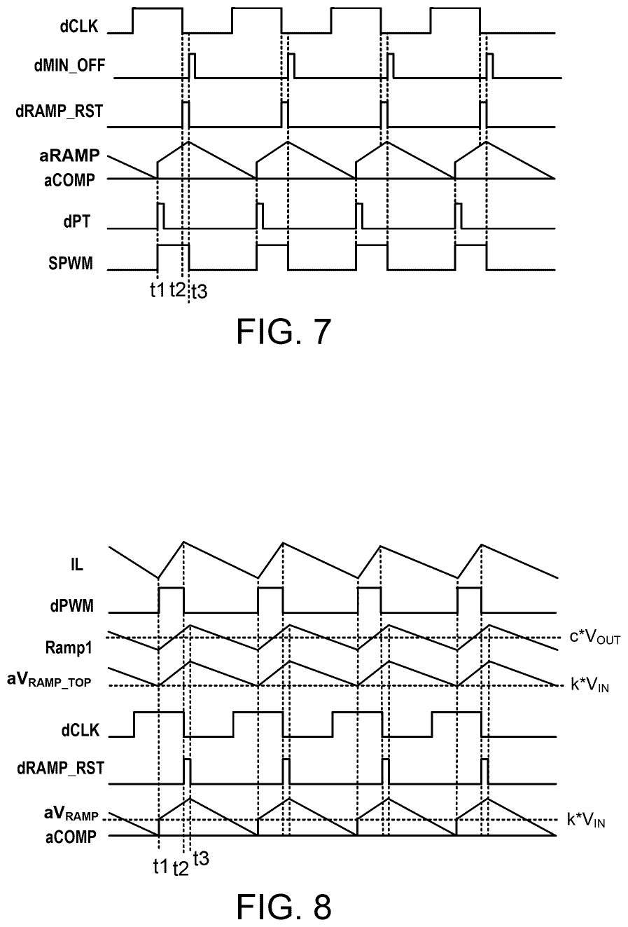

FIG. 7 is a schematic diagram of simulated waveforms of signals of the control circuit 500 as shown in FIG. 5 in accordance with an embodiment of the present disclosure. As shown in FIG. 5, when the ramp signal aRAMP cross over the compensation signal aCOMP at time t1, a pulse signal dPT is triggered, and the high side power switch M1 is turned on and the low side power switch M2 is turned off (e.g., SPWM at a high logic level). When the clock signal dCLK transitions from a high logic level to a low logic level at time t2, the signal dRAMP_RST is triggered. The duration of the signal dRAMP_RST should be long enough (e.g., 5 ns) to complete the reset of the compensation capacitor C_{SLOPE}.

After the compensation capacitor C_{SLOPE} is reset, the signal dMIN_OFF is triggered at time t3. When the signal dMIN_OFF is triggered at time t3, the signal SPWM transitions to a low logic level, i.e., the high side power switch M1 is turned off and the low side power switch M2 is turned on.

FIG. 8 is a schematic diagram of simulated waveforms of signals of the ramp generation circuit 600 as shown in FIG. 6 in accordance with an embodiment of the present disclosure. The PWM control signal (e.g., dPWM) is filtered by the PWM filter circuit 630 to generate the first ramp signal (e.g., Ramp1). As shown in FIG. 8, the first ramp signal Ramp1 is in phase with the inductor current IL. The amplitude of the first ramp signal Ramp1 is different from the inductor current IL. In one embodiment, the amplitude of the first ramp signal Ramp1 is adjusted by the AC tuning circuit 620. The DC bias of the first ramp signal Ramp1 is related to the output voltage V_{OUT}. After the first ramp signal Ramp1 is filtered by the high-pass filter circuit 640, and the DC bias is adjusted by the bias circuit 650, the ramp signal aV_{RAMP_TOP} is provided at a first terminal of the compensation capacitor C_{SLOPE}. As shown in FIG. 8, the DC bias of the ramp signal aV_{RAMP_TOP} is proportional to the input voltage (e.g., k*V_{IN}).

Specifically, the control switch S1 is turned on when the PWM control signal dPWM transitions to the high voltage level at time t1. Meanwhile, the compensation capacitor C_{SLOPE} is short-circuited and reset to provide the ramp signal aV_{RAMP}, and the ramp signal aV_{RAMP} increases as the ramp signal aV_{RAMP_TOP} increases during high side power switch M1 is turned on (e.g., dPWM is at the high voltage level). At time t2, the falling edge of the clock signal dCLK is triggered, and the PWM control signal dPWM transitions to the low voltage level to turn off the high side power switch M1 of the switching converter 12. Accordingly, the high side power switch M1 is turned off and the low side power switch M2 is turned on. At the same time, the signal dRAMP_RST is triggered by the falling edge of the clock signal dCLK. In one embodiment, the control switch S1 is reset by the signal dRAMP_RST for fixed frequency operation. Specifically, during transient event, the PWM control signal dPWM and the switching frequency may change. For instance, during the pulse (high voltage level) of the signal dRAMP_RST, the control switch S1 is turned on and the compensation capacitor C_{SLOPE} is reset. Meanwhile, the ramp signal aV_{RAMP} continues to increase as the ramp signal aV_{RAMP_TOP} increases. After the compensation capacitor C_{SLOPE} is reset, at time t3, the control switch S1 is turned off, and the ramp signal aV_{RAMP} decreases as the ramp signal aV_{RAMP_TOP} decreases during high side power switch M1 is turned off (e.g., dPWM is at the low voltage level). Since the control switch S1 is turned off, the compensation capacitor C_{SLOPE} is discharged by the current source I_{SLOPE} to generate the ramp signal aV_{RAMP} with a steeper slope to enhance the noise immunity.

For illustration purpose, the signals are switched synchronously (e.g., at time t1, t2, t3). However, the present disclosure is not limited thereto. In some embodiments, during switching between different states, a delay time may be set between the signals, or a delay may occur at the rising edge or the falling edge according to the practical application. Thus, the time points of the each signals could be adjusted, or with or without the delay time applied, to perform the function as the control circuit of the present disclosure.

It should be noted that, in the embodiment as shown in FIG. 8, the high side power switch M1 is turned on (i.e., the PWM control signal dPWM is at a high voltage level) when the value of the ramp signal aV_{RAMP} reaches the value of the compensation signal aCOMP, and the high side power switch M1 is turned off (i.e., the PWM control signal dPWM is at a low voltage level) in response to the clock signal dCLK. However, the present disclosure is not limited thereto. In another embodiment, the high side power switch M1 is turned on in response to the clock signal dCLK, and the high side power switch M1 is turned off when the value of the ramp signal aV_{RAMP} reaches the value of the compensation signal aCOMP.

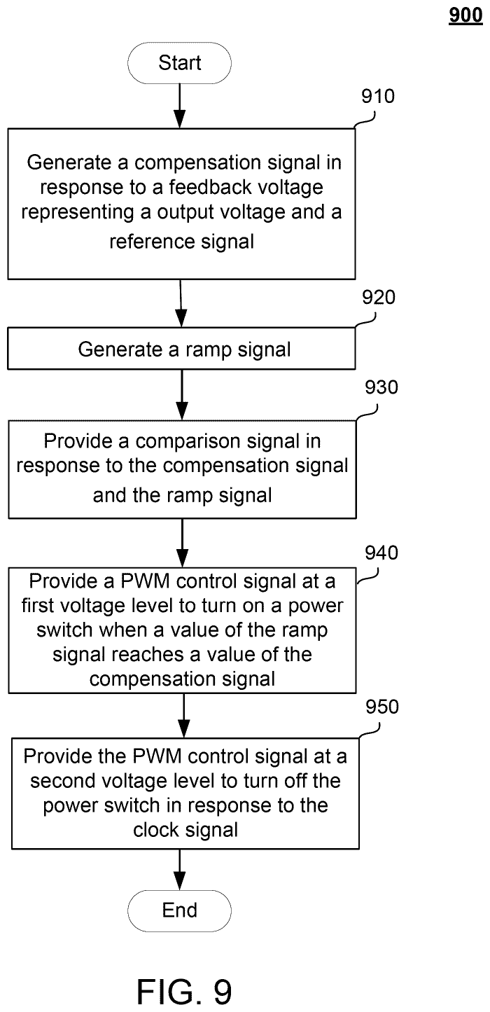

FIG. 9 is a flowchart of a method 900 for controlling a switching converter in accordance with an embodiment of the present disclosure. The switching converter includes at least a power switch to convert an input voltage into an output voltage. The method 900 include the following actions. In action 910, a compensation signal is generated in response to a feedback voltage representing a output voltage and a reference signal. In action 920, a ramp signal is generated. In action 930, a comparison signal is provided in response to the compensation signal and the ramp signal. In action 940, a PWM control signal at a first voltage level is provided to turn on a power switch when a value of the ramp signal reaches a value of the compensation signal. In action 950, the PWM control signal at a second voltage level is provided to turn off the power switch in response to the clock signal. Although the flowchart of FIG. 9 shows a sequential action. It is obvious to persons skilled the art that these actions could be performed in any order.

It should be understood that, the control circuit and the related components, circuit structures, signals, and waveforms described or shown above in the present disclosure are only for illustration purpose. However, the present disclosure is not limited thereto. Persons having ordinary skill in the art may understood that the control circuit of the present disclosure could be realized, according to practical applications, by any other circuits with different circuit structures, and thus controlled by different types of the corresponding signals to achieve the corresponding functions. For example, the compensation circuit, the ramp generation circuit, the comparison circuit and the logic circuit could be realized by a digital circuit, an analog circuit, a software, an automatic generation circuit by hardware description language, or a combination of the above.

Based on the above, the present disclosure provides various control circuits for switching converter and control method thereof. The control circuit in the present disclosure provides a loop control methodology for fixed frequency switching converter. For high-frequency applications, the ramp signal settling time is reduced by filtering the PWM signal as the ramp signal. Furthermore, the ramp generation circuit includes a high-pass filter circuit to filter the DC bias of the ramp signal that is related to the output voltage and loading current, and thus the transient response is improved. Moreover, by tracking the input voltage as the DC bias of the ramp signal, the switching converter could operate in a wider operating range (e.g., V_{IN}, V_{OUT}, and I_{OUT}). On top of that, a slope compensation circuit provides a slope current to increase the noise margin to avoid the false triggering oscillation.

It will be appreciated by persons skilled in the art that the present disclosure is not limited to what has been particularly shown and described herein above. Rather the scope of the present disclosure is defined by the claims and includes both combinations and sub-combinations of the various features described hereinabove as well as variations and modifications thereof which would occur to persons skilled in the art upon reading the foregoing description and which are not in the prior art.

What is claimed is:

1. A control circuit for a switching converter, wherein the switching converter having at least one power switch is configured to covert an input voltage into an output voltage in response to a pulse-width modulation (PWM) control signal, and the control circuit comprises:
a compensation circuit configured to generate a compensation signal in response to the output voltage and a reference signal;
a ramp generation circuit configured to generate a ramp signal in response to the PWM control signal;
a comparison circuit configured to provide a comparison signal in response to the compensation signal and the ramp signal; and
a logic circuit configured to provide the PWM control signal in response to the comparison signal and a clock signal.

2. The control circuit of claim 1, wherein a DC bias of the ramp signal is proportional to the input voltage.

3. The control circuit of claim 1, wherein the PWM control signal is at a first voltage level when a voltage value of the ramp signal reaches a voltage value of the compensation signal.

4. The control circuit of claim 1, wherein the PWM control signal is at a second voltage level in response to the clock signal.

5. The control circuit of claim 1, wherein the ramp generation circuit comprises:
a PWM filter circuit configured to filter the PWM control signal and generate a first ramp signal.

6. The control circuit of claim 5, wherein the ramp generation circuit further comprises:
a high-pass filter circuit configured to filter the first ramp signal and generate a second ramp signal.

7. The control circuit of claim 6, wherein the PWM filter circuit comprises a first resistor and a first capacitor, and the high-pass filter circuit comprises a second capacitor and a second resistor;
wherein a first terminal of the first resistor is configured to receive the PWM control signal, and a second terminal of the first resistor is coupled to a first terminal of the first capacitor to provide the first ramp signal; and
wherein a first terminal of the second capacitor is coupled to the first terminal of the first capacitor to receive the first ramp signal, and a second terminal of the second capacitor is coupled to a first terminal of the second resistor to provide the second ramp signal.

8. The control circuit of claim 5, wherein the ramp generation circuit further comprises:
a bias circuit configured to receive the first ramp signal and adjust a DC bias of the first ramp signal to provide the ramp signal.

9. The control circuit of claim 8, wherein the ramp generation circuit further comprises:
a second capacitor having a first terminal and a second terminal, wherein the first terminal of the second capacitor is coupled to the first terminal of the first capacitor to receive the first ramp signal;
a second resistor having a first terminal and a second terminal, wherein the first terminal of the second resistor is coupled to the second terminal of the second capacitor to provide the second ramp signal;
wherein the bias circuit comprises:
an operational amplifier having a first input terminal, a second input terminal, and an output terminal, wherein the first input terminal of the operational amplifier is configured to receive a bias voltage, and the output terminal of the operational amplifier is coupled to the second terminal of the second resistor;
a first transistor having a first terminal, a second terminal and a control terminal, wherein the control terminal of the first transistor is coupled to the output terminal of the operational amplifier, and the second terminal of the first transistor is coupled to the second input terminal of the operational amplifier; and
a second transistor having a first terminal, a second terminal and a control terminal, wherein the control terminal of the second transistor is coupled to the first terminal of the second resistor, and the second terminal of the second transistor is configured to provide a third ramp signal.

10. The control circuit of claim 5, wherein the ramp generation circuit further comprises:
a slope compensation circuit configured to generate the ramp signal in response to the first ramp signal and the clock signal, wherein the ramp signal is a periodic signal having a constant frequency set by the clock signal.

11. The control circuit of claim 10, wherein the ramp signal is generated by the slope compensation circuit in response to the PWM control signal.

12. The control circuit of claim 10, wherein the slope compensation circuit comprises:
a current source configured to provide a charging current;
a compensation capacitor coupled in series with the current source, wherein the compensation capacitor has a first terminal and a second terminal, the first terminal of the compensation capacitor is coupled to the PWM filter circuit to receive the first ramp signal, and the second terminal of the compensation capacitor is configured to provide the ramp signal; and
a control switch coupled in parallel with the compensation capacitor, wherein the control switch is controlled in response to the clock signal and the PWM control signal.

13. A control circuit for a switching converter, wherein the switching converter having at least one power switch is configured to covert an input voltage into an output voltage in response to a PWM control signal, and the control circuit comprises:
a compensation circuit configured to generate a compensation signal in response to a feedback signal representing the output voltage and a reference signal;
a ramp generation circuit configured to generate a ramp signal;
a comparison circuit configured to provide a comparison signal in response to the compensation signal and the ramp signal; and
a logic circuit configured to provide the PWM control signal in response to the comparison signal and a clock signal;
wherein the PWM control signal is at a first voltage level when a value of the ramp signal reaches a value of the compensation signal; and
wherein the PWM control signal is at a second voltage level in response to the clock signal.

14. The control circuit of claim 13, wherein the ramp signal is generated in response to the PWM control signal.

15. The control circuit of claim 13, wherein a DC bias of the ramp signal is proportional to the input voltage.

16. The control circuit of claim 13, wherein the ramp generation circuit comprises:
a PWM filter circuit configured to filter the PWM control signal and generate a first ramp signal.

17. The control circuit of claim 16, wherein the ramp generation circuit further comprises:
a high-pass filter circuit configured to filter the first ramp signal and generate a second ramp signal.

18. The control circuit of claim 17, wherein the PWM filter circuit comprises a first resistor and a first capacitor, and the high-pass filter circuit comprises a second capacitor and a second resistor;
wherein a first terminal of the first resistor is configured to receive the PWM control signal, and a second terminal of the first resistor is coupled to a first terminal of the first capacitor to provide the first ramp signal; and
wherein a first terminal of the second capacitor is coupled to the first terminal of the first capacitor to receive the first ramp signal, and a second terminal of the second capacitor is coupled to a first terminal of the second resistor to provide the second ramp signal.

19. The control circuit of claim 16, wherein the ramp generation circuit further comprises:
a bias circuit configured to receive the first ramp signal and adjust a DC bias of the first ramp signal to provide the ramp signal.

20. The control circuit of claim 19, wherein the ramp generation circuit further comprises:
a second capacitor having a first terminal and a second terminal, wherein the first terminal of the second capacitor is coupled to the first terminal of the first capacitor to receive the first ramp signal;
a second resistor having a first terminal and a second terminal, wherein the first terminal of the second resistor is coupled to the second terminal of the second capacitor to provide the second ramp signal;
wherein the bias circuit comprises:
an operational amplifier having a first input terminal, a second input terminal, and an output terminal, wherein the first input terminal of the operational amplifier is configured to receive a bias voltage, and the output terminal of the operational amplifier is coupled to the second terminal of the second resistor;
a first transistor having a first terminal, a second terminal and a control terminal, wherein the control terminal of the first transistor is coupled to the output terminal of the operational amplifier, and the second terminal of the first transistor is coupled to the second input terminal of the operational amplifier; and
a second transistor having a first terminal, a second terminal and a control terminal, wherein the control terminal of the second transistor is coupled to the first terminal of the second resistor, and the second terminal of the second transistor is configured to provide a third ramp signal.

21. The control circuit of claim 16, wherein the ramp generation circuit further comprises:
a slope compensation circuit configured to generate the ramp signal in response to the first ramp signal, the clock signal and the PWM control signal, wherein the ramp signal is a periodic signal having a constant frequency set by the clock signal.

22. The control circuit of claim 21, wherein the slope compensation circuit comprises:
a current source configured to provide a charging current;
a compensation capacitor coupled in series with the current source, wherein the compensation capacitor has a first terminal and a second terminal, the first terminal of the compensation capacitor is coupled to the PWM filter circuit to receive the first ramp signal, and the second terminal of the compensation capacitor is configured to provide the ramp signal; and
a control switch coupled in parallel with the compensation capacitor, wherein the control switch is controlled in response to the clock signal and the PWM control signal.
